(19) United States
(12) Patent Application Publication
(10) Pub. No.: US 2025/0143042 A1
(43) Pub. Date: May 1, 2025

(54) MICRO LIGHT-EMITTING DIODE PACKAGE STRUCTURE

(71) Applicant: Lextar Electronics Corporation, Hsinchu City (TW)

(72) Inventors: Shiou-Yi KUO, Hsinchu (TW); Bo-Yu CHEN, Hsinchu (TW)

(21) Appl. No.: 18/826,668

(22) Filed: Sep. 6, 2024

(30) Foreign Application Priority Data
Nov. 1, 2023 (TW) 112141946

(51) Int. Cl. H01L 33/62; H01L 25/075; H01L 25/16; H01L 27/12

(52) U.S. Cl. CPC H10H 20/857; H01L 25/0753; H01L 25/167; H10D 86/481; H10D 86/60

(57) ABSTRACT

A micro light-emitting diode package structure is provided. The micro light-emitting diode package structure includes a plurality of micro light-emitting diode chips, a light-transmitting layer, a first insulating layer, a driving element, and a redistribution layer. The micro light-emitting diode chips are disposed side by side, wherein each micro light-emitting diode chip includes an electrode surface and a light-emitting surface opposite to each other. The light-transmitting layer covers the light-emitting surfaces of the micro light-emitting diode chips. The first insulating layer is disposed below the micro light-emitting diode chips. The driving element is disposed in the first insulating layer, wherein the driving element includes a plurality of electrodes, and the electrodes are on the side of the driving element away from the micro light-emitting diode chips. The redistribution layer electrically connects the electrode surfaces of the micro light-emitting diode chips and the electrodes of the driving element.

### CROSS REFERENCE TO RELATED APPLICATIONS

This application claims priority of Taiwan Patent Application No. 112141946, filed on Nov. 1, 2023, the content of the entirety of which is incorporated by reference herein.

### Technical Field

The present disclosure relates to a light-emitting diode, and in particular, it relates to a micro light-emitting diode package structure.

### BACKGROUND

### Description of the Related Art

With the rapid development of electronic devices, various elements of the electronic devices are gradually being scaled down. Taking the micro light-emitting diode package structure as an example, it is limited by circuit layout and component manufacturing process to be usually challenging to achieve high brightness uniformity and high contrast under scaling down. Therefore, although existing micro light-emitting diode package structures have largely met their intended purposes, they do not meet requirements in all respects. Therefore, there are still some issues to overcome regarding the micro light-emitting diode package structure.

### SUMMARY

In some embodiments, a micro light-emitting diode package structure is provided. The micro light-emitting diode package structure includes a plurality of micro light-emitting diode chips, a light-transmitting layer, a first insulating layer, a driving element, and a redistribution layer. The micro light-emitting diode chips are disposed side by side, wherein each of the micro light-emitting diode chips includes an electrode surface and a light-emitting surface opposite to each other. The light-transmitting layer covers the light-emitting surfaces of the micro light-emitting diode chips. The first insulating layer is disposed below the micro light-emitting diode chips. The driving element is disposed in the first insulating layer, wherein the driving element includes a plurality of electrodes, and the electrodes are on the side of the driving element away from the micro light-emitting diode chips. The redistribution layer electrically connects the electrode surfaces of the micro light-emitting diode chips and the electrodes of the driving element.

The micro light-emitting diode package structure and the forming method thereof of the present disclosure are able to be applied on various electronic devices. In order to make the features and advantages of the present disclosure more readily be understood, various embodiments are given in the subsequent description in conjunction with the accompanying drawings.

### BRIEF DESCRIPTION OF THE DRAWINGS

Aspects of the present disclosure are better understood from the following detailed description when read with the accompanying FIGS. It is worth noting that some features may not be drawn to scale in accordance with the standard practice in the industry. In fact, the dimensions of the various features may be arbitrarily increased or reduced for clarity of discussion.

FIG. 1 is a schematic cross-sectional view showing the micro light-emitting diode package structure at various stages in the formation method according to some embodiments of the present disclosure;

FIG. 2 is a schematic diagram showing the upper surfaces of blue LED chips and green LED chips with periodically arranged concave and convex textures according to some embodiments of the present disclosure;

FIGS. 3 to 6 are schematic cross-sectional views showing the micro light-emitting diode package structure at various stages in the formation method according to some embodiments of the present disclosure;

FIG. 7 is a schematic top view showing the micro light-emitting diode package structure at various stages in the formation method according to some embodiments of the present disclosure;

FIGS. 8 to 10 are schematic cross-sectional views showing the micro light-emitting diode package structure at various stages in the formation method according to some embodiments of the present disclosure;

FIG. 11 is a schematic top view showing the micro light-emitting diode package structure at various stages in the formation method according to some embodiments of the present disclosure;

FIG. 12 is a circuit schematic diagram showing the micro light-emitting diode package structure according to some embodiments of the present disclosure;

FIGS. 13 to 17 are schematic cross-sectional views showing the micro light-emitting diode package structure at various stages in the formation method according to some embodiments of the present disclosure;

FIG. 18 is a schematic top view showing the micro light-emitting diode package structure at various stages in the formation method according to some embodiments of the present disclosure;

FIG. 19 is a schematic top view showing the micro light-emitting diode package structure at various stages in the formation method according to other embodiments of the present disclosure;

FIG. 20 is a schematic cross-sectional view showing the micro light-emitting diode package structure according to some embodiments of the present disclosure;

FIG. 21 is a schematic cross-sectional view showing the display device according to other embodiments of the present disclosure;

FIG. 22 is a schematic top view showing the display device according to other embodiments of the present disclosure;

FIG. 23 is a schematic top view showing the display device according to further embodiments of the present disclosure;

FIG. 24 is a schematic cross-sectional view showing the micro light-emitting diode package structure at various stages in the formation method according to further embodiments of the present disclosure; and

FIG. 25 is a schematic cross-sectional view showing the micro light-emitting diode package structure at various stages in the formation method according to further embodiments of the present disclosure.

### DETAILED DESCRIPTION

The following disclosure provides many different embodiments, or examples, for implementing the micro light-emitting diode package structure and the forming method thereof. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat symbols and/or characters of components in different embodiments or examples. This repetition is for simplicity and clarity, rather than to represent the relationship between the different embodiments and/or examples discussed.

In some embodiments of the present disclosure, the terms regarding disposing or connecting such as “on,” “connected to,” “coupled to”, or other similar terms, unless specifically defined, may mean that two components are in direct contact, or mean that two components are not in direct contact which includes the case where another component is interposed between them. The terms regarding disposing or connecting may also include the case where both structures are movable or both structures are fixed.

In addition, in the specification or the claims, ordinal numbers such as “first”, “second”, and other similar terms are used to name different components or distinguish different embodiments or scopes, not to limit the upper or lower limit of the number of features, nor to limit the manufacturing sequence of features or disposing sequence of features.

Herein, the terms “approximately”, “about”, and “substantially” generally mean within 10%, within 5%, within 3%, within 2%, within 1%, or within 0.5% of a given value or range. The given value is an approximate value, that is, “approximately”, “about”, and “substantially” can still be implied without the specific description of “approximately”, “about”, and “substantially”. The phrase “a range between a first value and a second value” means that the range includes the first value, the second value, and other values in between. Furthermore, any two values or directions used for comparison may have certain tolerance. If the first value is equal to the second value, it implies that there may be a tolerance within about 10%, within 5%, within 3%, within 2%, within 1%, or within 0.5% between the first value and the second value. If the first direction is perpendicular to the second direction, the angle between the first direction and the second direction may be between 80 degrees and 100 degrees. If the first direction is parallel to the second direction, the angle between the first direction and the second direction may be between 0 degrees and 10 degrees.

Unless otherwise defined, all terms (including technical and scientific terms) used herein have the same meaning as commonly understood by a person skilled in the art to which the invention pertains. It will be further understood that terms, such as those defined in commonly used dictionaries, should be interpreted as having a meaning consistent with the relevant technology and the context or background of the present disclosure and will not be interpreted in an idealized or overly formal sense unless expressly so defined herein.

It should be noted that, for clarity of explanation, some features of the device are omitted in the drawings, and only some features are schematically illustrated. In some embodiments, additional features may be added to the electronic device of the present disclosure. In some embodiments, some features of the device disclosed herein may be replaced or omitted. It should be understood that, in some embodiments, additional processing steps may be provided before, during, and/or after the forming method of the device. In some embodiments, some of the described processing steps may be replaced or omitted, and the order of some of the described processing steps may be interchangeable.

In the prior art, the driving methods of light-emitting diode (LED) display devices may be roughly divided into two types: passive matrix (PM) and active matrix (AM). Among them, the passive matrix refers to a driving method that uses one driver chip to drive multiple groups of light-emitting diode components (for example, each group of light-emitting diode components includes red, blue, and green LED chips), while the active matrix refers to a driving method that uses one driver chip to drive one group of light-emitting diode components. However, although the active matrix has better brightness uniformity and contrast, it is difficult to be widely used in all substrates due to its complex structure. To this end, the present disclosure provides a micro light-emitting diode package structure using a method in the active matrix and a forming method thereof. Through specific formation methods and structural configurations, the present disclosure can provide integrated circuits for driving micro light-emitting diodes on a substrate such as a printed circuit board (PCB) so that this active matrix driving method is implemented on the substrate.

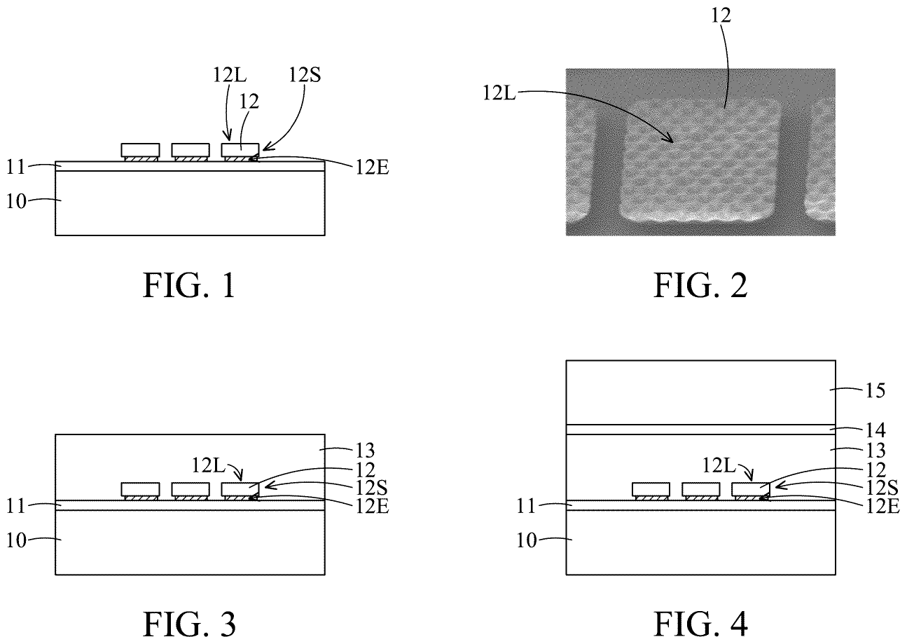

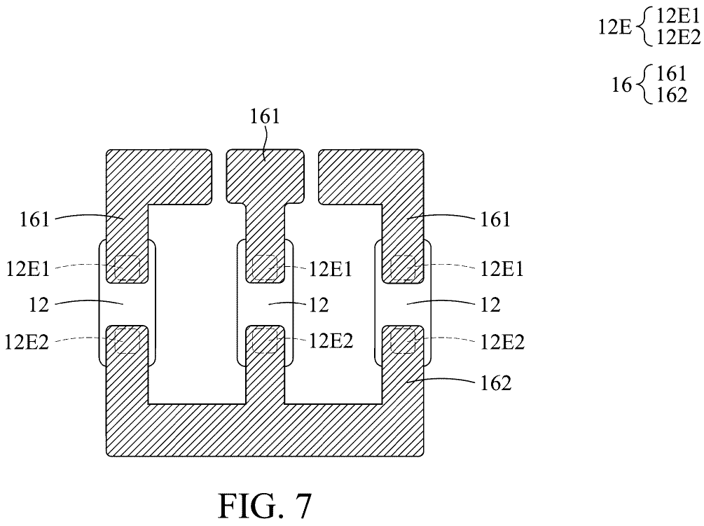

FIGS. 1, 3-6, 8-10, 13-17, and 20 are schematic cross-section views showing the micro light-emitting diodes package structure at different stages in the formation method according to some embodiments of the present disclosure. On the other hand, FIGS. 7, 11, and 18 are schematic top views showing the micro light-emitting diode package structure at different stages in the formation method according to some embodiments of the present disclosure.

As shown in FIG. 1, a first substrate 10 is provided. In some embodiments, the first substrate 10 may be a Group IV compound. In some embodiments, the first substrate 10 may be or may include silicon (Si), diamond (C), or silicon carbide (SiC). In some embodiments, the first substrate 10 may be or may include sapphire. In some embodiments, the first substrate 10 may be a III-V compound. In some embodiments, the first substrate 10 may be or may include gallium nitride (GaN), aluminum gallium nitride (AlGaN), aluminum nitride (AlN), gallium phosphide (GaP), gallium arsenide (GaAs), aluminum gallium arsenide (AlGaAs), combinations thereof, or other suitable substrates, but the present disclosure is not limited thereto. In some embodiments, the first substrate 10 may be or may include gallium oxide (Ga₂O₃). For example, the first substrate 10 may be a sapphire substrate.

Following the above process, a first debond layer 11 is disposed on the first substrate 10. In some embodiments, the first debond layer 11 may be or may include thermal release glue, UV release glue, combinations thereof, or other suitable materials, but the present disclosure is not limited thereto. It should be noted that although FIG. 1 illustrates an embodiment in which the first debond layer 11 completely covers the upper surface of the first substrate 10, but the present disclosure is not limited thereto. In other embodiments, the first debond layer 11 may partially cover the upper surface of the first substrate 10. For example, the first debond layer 11 may partially cover the upper surface of the first substrate 10 corresponding to the position of a micro light-emitting diode chip that will be disposed later.

Following the above process, the plurality of micro light-emitting diode chips 12 are disposed side by side on the first debond layer 11. For example, the plurality of micro light-emitting diode chips 12 may be transferred to the first debond layer 11 through a pick-up process or a laser transfer process. In some embodiments, the micro light-emitting diode chips 12 each have a light-emitting surface 12L, an electrode portion 12E, and a plurality of side surfaces 12S. The electrode portion 12E and the light-emitting surface 12L are opposite to each other, and the plurality of side surfaces 12S are between the electrode portion 12E and the light-emitting surface 12L. In some embodiments, the electrode portion 12E of the micro light-emitting diode chip 12 is configured to electrically connect other electronic elements or electronic devices, and the light-emitting surface 12L is configured to generate a light source. In these embodiments, the electrode portion 12E of the micro light-emitting diode chip 12 faces the first substrate 10, and the light-emitting surface 12L faces away from the first substrate 10.

In some embodiments, the micro light-emitting diode chip 12 may be a red LED chip, a blue LED chip, or a green LED chip. The light-emitting surfaces of the red LED chip, blue LED chip, and green LED chip have textures. FIG. 2 is a photo of the upper surface (that is, the light-emitting surface 12L) of the blue LED chip and the green LED chip having periodically arranged concave and convex textures. In some embodiments, the micro light-emitting diode chip 12 is provided without the sapphire substrate, and the micro light-emitting diode chip 12 has periodical concave and convex textures after laser lifting off the sapphire substrate, such as the blue LED chip or the green LED chip. The concave and convex texture is used to enhance light extraction and adjust the viewing angle of the micro light-emitting diode chip 12. In some embodiments, the light-emitting surface 12L of the red LED chip has a non-uniform texture. In some embodiments, the micro light-emitting diode chips 12 may be or may include the micro light-emitting diode chips 12 in flip-chip type.

As shown in FIG. 3, a light-transmitting layer 13 is disposed to cover the light-emitting surface 12L of the micro light-emitting diode chip 12, and the light-transmitting layer 13 covers the side surfaces 12S of the micro light-emitting diode chip 12. For example, the light-transmitting layer 13 may be blanketly formed on the micro light-emitting diode chip 12 by compression molding, lamination, transfer molding, other suitable methods, or combinations thereof. In some embodiments, the light-transmitting layer 13 may be or may include epoxy, silicone, polyurethane, combinations thereof, or other suitable materials, but the present disclosure is not limited thereto.

As shown in FIG. 4, a second debond layer 14 and a second substrate 15 are disposed on the light-transmitting layer 13. For example, the second debond layer 14 may be disposed on the second substrate 15, and then the second substrate 15 may be bonded to the light-transmitting layer 13 through the second debond layer 14. Alternatively, the second debond layer 14 may also be disposed on the light-transmitting layer 13, and then the second substrate 15 is bonded to the second debond layer 14. In some embodiments, the second debond layer 14 may be or may include pyrolytic glue, photolytic glue, combinations thereof, or other suitable materials, but the present disclosure is not limited thereto. In some embodiments, the material of the second debond layer 14 may be similar or the same as the material of the first debond layer 11, but the present disclosure is not limited thereto. In some embodiments, the second substrate 15 may be a Group IV compound. In some embodiments, the second substrate 15 may be or may include silicon, diamond, or silicon carbide. In some embodiments, the second substrate 15 may be a III-V compound. In some embodiments, the second substrate 15 may be sapphire. In some embodiments, the second substrate 15 may be gallium nitride, aluminum gallium nitride, aluminum nitride, gallium phosphide, gallium arsenide, aluminum gallium arsenide, combinations thereof, or other suitable substrates, but the present disclosure is not limited thereto. In some embodiments, the second substrate 15 may be or may include gallium oxide. In some embodiments, the material of the second substrate 15 may be similar or the same as the material of the first substrate 10, but the present disclosure is not limited thereto.

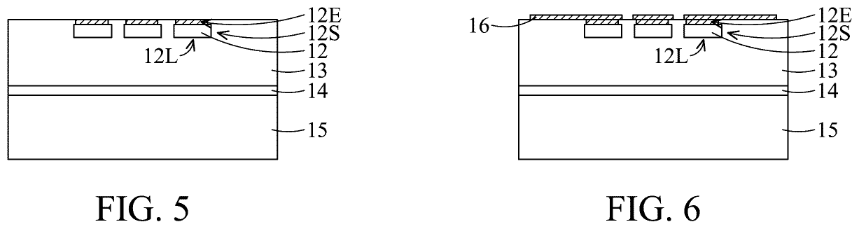

As shown in FIG. 5, the first substrate 10 is turned over, and the first substrate 10 and the first debond layer 11 are removed. In some embodiments, depending on the type of the first debond layer 11, the first debond layer 11 may lose its adhesion by heating, UV light, laser, etc., so as to remove the first substrate 10 thereon. Then, the first debond layer 11 is removed by physical means or chemical means. It should be noted that the first debond layer 11 and the first substrate 10 may also be removed simultaneously in the same step using a suitable process, which is not limited to the above method.

As shown in FIG. 6, a first redistribution layer 16 is formed on the light-transmitting layer 13 along the horizontal direction of the light-transmitting layer 13, and the first redistribution layer 16 electrically connects the micro light-emitting diode chip 12. In some embodiments, the first redistribution layer 16 may be formed by electroplating, evaporation, screen printing, vacuum spraying, combinations thereof, or other suitable methods, but the present disclosure is not limited thereto. In some embodiments, the first redistribution layer 16 may be or may include a conductive material. For example, the conductive material may include metal, metal compounds, other suitable conductive materials, or combinations thereof, but the present disclosure is not limited thereto. For example, the metal may be tin (Sn), copper (Cu), gold (Au), silver (Ag), nickel (Ni), indium (In), platinum (Pt), palladium (Pd), iridium (Ir), titanium (Ti), chromium (Cr), tungsten (W), aluminum (Al), molybdenum (Mo), titanium (Ti), magnesium (Mg), zinc (Zn), germanium (Ge), or their alloys. For example, the metal compound may be tantalum nitride (TaN), titanium nitride (TiN), tungsten silicide (WSi₂), indium tin oxide (ITO), etc. For example, the conductive material of the first redistribution layer 16 may be aluminum copper (AlCu).

FIG. 7 is a schematic top view showing the micro light-emitting diode package structure. For ease of understanding, elements such as the light-transmitting layer 13, the second debond layer 14, and the second substrate 15 are omitted in FIG. 7. Referring to FIG. 7, the first redistribution layer 16 may include three first sub-redistribution layers 161 and one second sub-redistribution layer 162. On the other hand, the micro light-emitting diode package structure has three micro light-emitting diode chips 12 disposed side by side, and each micro light-emitting diode chip 12 has an electrode portion 12E1 and an electrode portion 12E2. In subsequent processes, the electrode portions 12E1 of the three micro light-emitting diode chips 12 may each connect different anodes through the three first sub-redistribution layers 161, and connect the same cathode through the same second sub-redistribution layer 162 to form a common cathode LED structure. In some embodiments, the second sub-redistribution layer 162 may be E-shaped to facilitate electrical connection. In some embodiments, the second sub-redistribution layer 162 may be in a strip shape to facilitate electrical connection. In some embodiments, the three first sub-redistribution layers 161 may be approximately L-shaped and T-shaped so as to facilitate electrical connection. Alternatively, the electrode portions 12E1 of the three micro light-emitting diode chips 12 may each connect different cathodes through three first sub-redistribution layers 161, and connect the same anode through the same second sub-redistribution layer 162 to form a common anode LED structure.

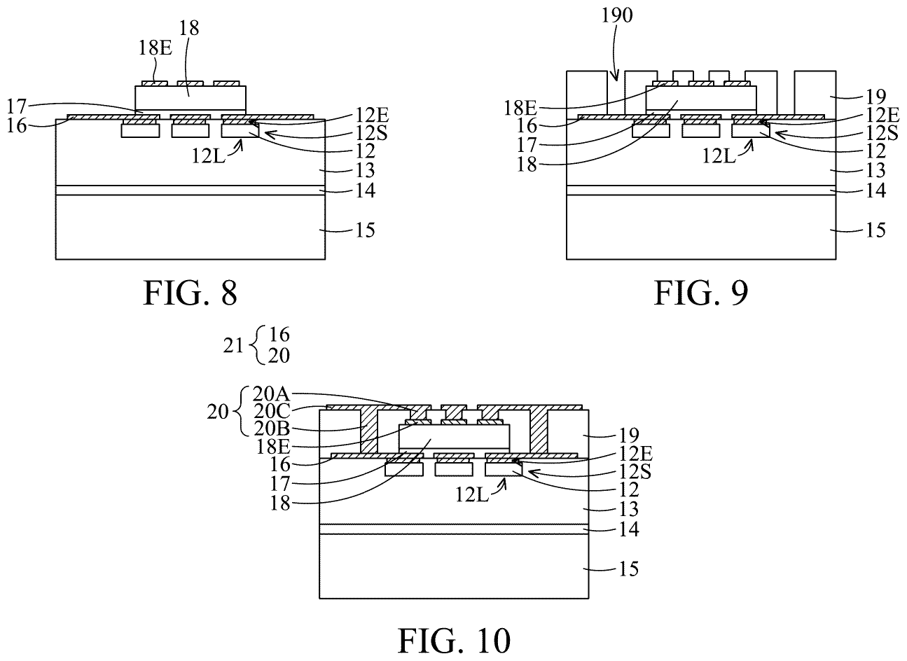

As shown in FIG. 8, an adhesive layer 17 and a driving element 18 are disposed on the first redistribution layer 16. For example, the adhesive layer 17 may be disposed on the driving element 18 first, and the driving element 18 may be transferred to the first redistribution layer 16 along with the adhesive layer 17. Alternatively, the adhesive layer 17 may be disposed on the first redistribution layer 16 first, and the driving element 18 may be attached to the adhesive layer 17. In some embodiments, the adhesive layer 17 may be or may include polyimide (PI), polybenzoxazole (PBO), epoxy, combinations thereof, or other suitable materials, but the present disclosure is not limited thereto.

In some embodiments, the driving element 18 includes a plurality of electrodes 18E. In the present disclosure, the electrodes 18E of the driving element 18 do not face the micro light-emitting diode chip 12 but is on the side of the driving element 18 away from the first redistribution layer 16. In other words, there is a long physical distance between the electrodes 18E of the driving element 18 and the electrode portion 12E of the micro light-emitting diode chip 12. In this way, this distance may be used as a spatial buffer, and the first redistribution layer 16 and a second redistribution layer 20 that will be deposed may electrically connect these electrodes 18E to the electrode portion 12E of the micro light-emitting diode chip 12.

As shown in FIG. 9, a first insulating layer 19 is disposed on the light-transmitting layer 13, the first redistribution layer 16, and the driving element 18, wherein the first insulating layer 19 exposes the first redistribution layer 16 and the electrodes 18E of the driving element 18 by the through holes 190. In some embodiments, the through holes 190 may be formed by a photolithography process, a drilling process, combinations thereof, or other suitable processes, but the present disclosure is not limited thereto. In some embodiments, the first insulating layer 19 may be or may include epoxy resin, polyimide (PI), polybenzoxazole (PBO), silicone resin, silicon dioxide, silicon nitride, or combinations thereof, but the present disclosure is not limited thereto. In some embodiments, the material of the first insulating layer 19 may be the same as the material of the light-transmitting layer 13.

As shown in FIG. 10, the second redistribution layer 20 is disposed on the first insulating layer 19, wherein the second redistribution layer 20 passes through the first insulating layer 19 by the through holes 190 to electrically connect the first redistribution layer 16 and electrodes 18E of driving element 18. In a cross-sectional view, the second redistribution layer 20 may include a first vertical extension portion 20A, a second vertical extension portion 20B, and a horizontal extension portion 20C. For example, the step of disposing the second redistribution layer 20 may include: forming a first vertical extension portion 20A, wherein the first vertical extension portion 20A passes through the first insulating layer 19 and electrically connects the electrodes 18E of the driving element 18; forming the second vertical extension portion 20B, wherein the second vertical extension portion 20B passes through the first insulating layer 19 and electrically connects the first redistribution layer 16; and forming the horizontal extension portion 20C, wherein the horizontal extension portion 20C extends along the surface of the first insulating layer 19 away from the light-transmitting layer 13 and electrically connects the first vertical extension portion 20A and the second vertical extension portion 20B. In some embodiments, the first vertical extension portion 20A, the second vertical extension portion 20B, and the horizontal extension portion 20C may be formed in the same process, but the present disclosure is not limited thereto. In some embodiments, the length of the second vertical extension portion 20B is greater than the length of the first vertical extension portion 20A.

In some embodiments, the second redistribution layer 20 may be formed by electroplating, evaporation, screen printing, vacuum spraying, combinations thereof, or other suitable methods, but the present disclosure is not limited thereto. In some embodiments, the second redistribution layer 20 may be or may include a conductive material. For example, the conductive material may include metal, metal compounds, other suitable conductive materials, or combinations thereof, but the present disclosure is not limited thereto. For example, the metal may be tin, copper, gold, silver, nickel, indium, platinum, palladium, iridium, titanium, chromium, tungsten, aluminum, molybdenum, titanium, magnesium, zinc, germanium, or alloys thereof. For example, the metal compound may be tantalum nitride, titanium nitride, tungsten silicide, indium tin oxide, etc. For example, the conductive material of the second redistribution layer 20 may be aluminum copper (AlCu). In some embodiments, the material of the second redistribution layer 20 may be similar or the same as the material of the first redistribution layer 16, but the present disclosure is not limited thereto.

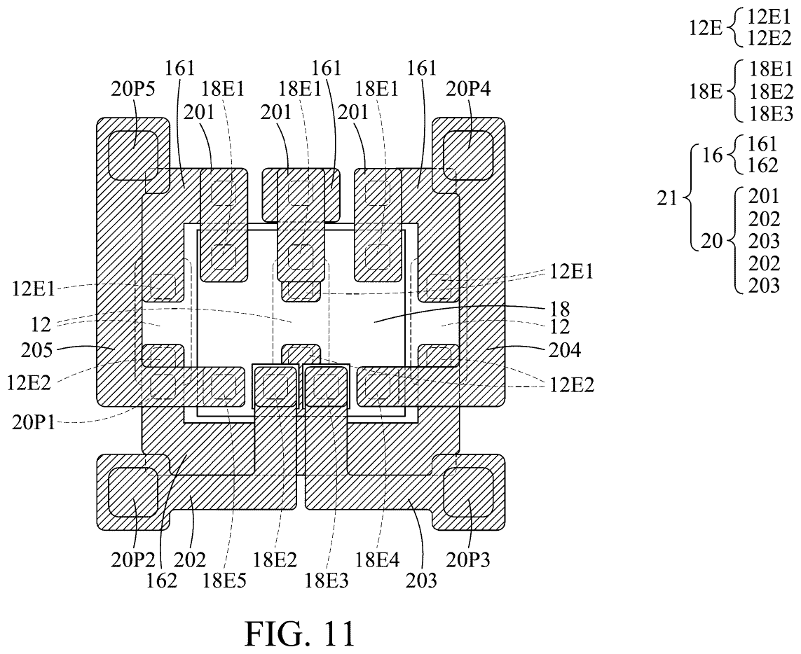

FIG. 11 is a schematic top view showing the micro light-emitting diode package structure. For ease of understanding, elements such as the light-transmitting layer 13, the second debond layer 14, the second substrate 15, and the first insulating layer 19 are omitted in FIG. 11. As shown in the figure, from the top view, the second redistribution layer 20 may include three third sub-redistribution layers 201 electrically connecting the micro light-emitting diode chips 12, one fourth sub-redistribution layer 202 electrically connecting the column line (for example, select line), one fifth sub-redistribution layer 203 electrically connecting the row line (for example, data line), one sixth sub-redistribution layer 204 electrically connecting the voltage source, and one seventh sub-redistribution layer 205 electrically connecting the ground line.

On the other hand, the plurality of electrodes 18E of the driving element 18 may include seven electrodes, which are three electrodes 18E1, one electrode 18E2, one electrode 18E3, one electrode 18E4, and one electrode 18E5. Specifically, the electrodes 18E1 of the driving element 18 may electrically connect the electrode portion 12E1 of the micro light-emitting diode chip 12 through the third sub-redistribution layer 201 and the first sub-redistribution layer 161. The electrodes 18E2 of the driving element 18 may electrically connect the row line (for example, select line) through the fourth sub-redistribution layer 202. The electrode 18E3 of the driving element 18 may electrically connect the column line (for example, data line) through the fifth sub-redistribution layer 203. The electrode 18E4 of the driving element 18 may electrically connect the voltage source through the sixth sub-redistribution layer 204. The electrode 18E5 of the driving element 18 may electrically connect the ground line through the seventh sub-redistribution layer 205.

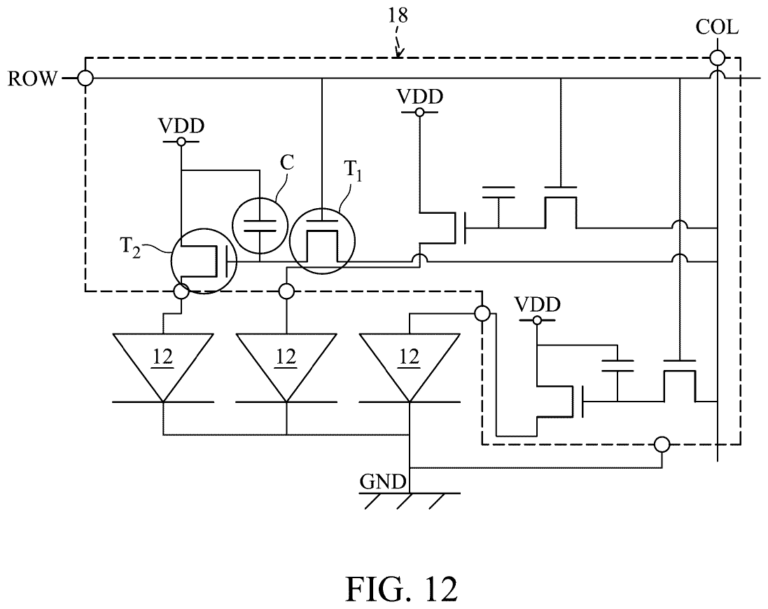

FIG. 12 is a schematic circuit diagram showing the micro light-emitting diode package structure according to some embodiments of the present disclosure. As shown in the figure, the driving element 18 of the micro light-emitting diode package structure 1 may separately control the three micro light-emitting diode chips 12 by using the driving circuit design of three groups of 2T1C structures (that is, two transistors T1, T2, and one capacitor C). On the other hand, the driving element 18 has the seven electrodes as described above, which electrically connect the external devices such as voltage source VDD, the ground line GND, the column line COL (for example, select line), row line ROW (for example, data line), and the internal devices such as the anodes (for example, the electrode portions 12E1) of the three micro light-emitting diode chips 12. In some embodiments, digital signals (including 0 and 1) may be input to the column line COL and the row line ROW through pulse width modulation (PWM) technology so that the three micro light-emitting diode chips 12 are determined to turn on or off through the driving element 18.

For example, when the digital signal of (1,1) is input to the column line COL and the row line ROW, the transistor T1 is turned on. When transistor T1 is turned on, current flows to the gate of transistor T2, causing transistor T2 to turn on. As a result, the voltage source VDD provides current to the micro light-emitting diode chip 12, causing the micro light-emitting diode chip 12 to light up. In addition, the stored charge of the capacitor C may determine the lighting time of the micro light-emitting diode chip 12. It should be noted that the above circuit schematic diagram adopts a common cathode structure configuration, but the present disclosure is not limited thereto. In other embodiments, a common anode structure may also be adopted according to actual needs.

Referring still to FIG. 11, the seventh sub-redistribution layer 205 may further electrically connect the second sub-redistribution layer 162 through a connecting member 20P1. In this way, the three-electrode portions 12E2 of the three micro light-emitting diode chips 12 that electrically connect the second sub-redistribution layer 162 may be common to the same ground line or voltage source with the electrodes 18E5 of the driving element 18 that electrically connect the seventh sub-redistribution layer 205, to reduce the amount of wiring. For example, when the seventh sub-redistribution layer 205 electrically connects the ground line, the three micro light-emitting diode chips 12 and the driving element 18 commonly connect the same ground line to form a common cathode structure. At this time, the three micro light-emitting diode chips 12 and the driving element 18 connect different anodes (voltage sources) through the first sub-redistribution layer 161 and the sixth sub-redistribution layer 204. On the contrary, when the seventh sub-redistribution layer 205 electrically connects the voltage source, the three micro light-emitting diode chips 12 and the driving element 18 commonly connect the same voltage source to form a common anode structure. At this time, the three micro light-emitting diode chips 12 and the driving element 18 connect different cathodes through the first sub-redistribution layer 161 and the sixth sub-redistribution layer 204.

In some embodiments, the second redistribution layer 20 may further include a connecting member 20P2 for connecting the column line COL, a connecting member 20P3 for connecting the row line ROW, a connecting member 20P4 for connecting the voltage source VDD, and a connecting member 20P5 for connecting the ground line GND. Among them, the connecting member 20P2 is disposed on the fourth sub-redistribution layer 202, the connecting member 20P3 is disposed on the fifth sub-redistribution layer 203, the connecting member 20P4 is disposed on the sixth sub-redistribution layer 204, and the connecting member 20P5 is disposed on the seventh sub-redistribution layer 205. In some embodiments, the connecting members 20P1 to 20P5 may be or may include pads, but the present disclosure is not limited thereto.

In some embodiments, the first redistribution layer 16 and the second redistribution layer 20 may be collectively referred to as a redistribution layer 21. The redistribution layer 21 electrically connects the electrode 18E (for example, the electrode 18E1) of the driving element 18 and the electrode portion 12E (for example, the electrode portion 12E1) of the micro light-emitting diode chip 12 through the above configuration. In addition, the redistribution layer 21 may further connect the electrodes 18E (for example, electrodes 18E2 to 18E5) of the driving element 18 to the column line COL (select line), the row line ROW (data line), the voltage source VDD, and the GND through the above configuration.

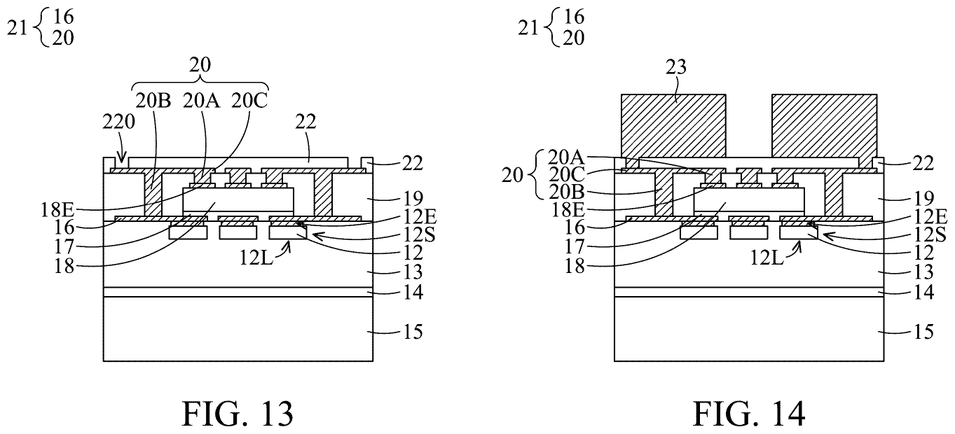

As shown in FIG. 13, a second insulating layer 22 is disposed on the second redistribution layer 20. The second insulating layer 22 exposes the second redistribution layer 20 by a through holes 220. In some embodiments, the through hole 220 may be formed by a photolithography process, a drilling process, combinations thereof, or other suitable processes, but the present disclosure is not limited thereto. In some embodiments, the second insulating layer 22 may be or may include epoxy resin, polyimide, polyphenylene oxazole, silicone resin, silicon oxide, silicon nitride, or combinations thereof, but the present disclosure is not limited thereto. In some embodiments, the material of the second insulating layer 22 may be the same as the material of the first insulating layer 19. In some embodiments, the material of the second insulating layer 22 may be different from the material of the first insulating layer 19.

As shown in FIG. 14, a plurality of conductive members 23 are disposed, wherein the conductive members 23 pass through the second insulating layer 22 by the through holes 220 to electrically connect to the second redistribution layer 20 of the redistribution layer 21. More specifically, the conductive member 23 electrically connects the horizontal extension portion 20C of the second redistribution layer 20. In some embodiments, the conductive members 23 may be metal pillars, but the present disclosure is not limited thereto. In some embodiments, the conductive member 23 may be formed by electroplating or other suitable methods, but the present disclosure is not limited thereto. In some embodiments, the material of the conductive member 23 may be similar or the same as the material of the first redistribution layer 16 or the second redistribution layer 20, but the present disclosure is not limited thereto. In some embodiments, the material of the conductive member 23 may be different from the material of the first redistribution layer 16 or the second redistribution layer 20.

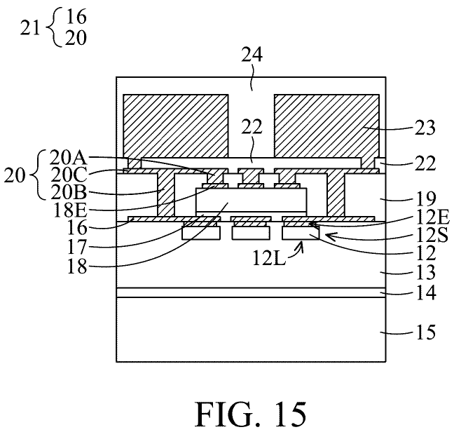

As shown in FIG. 15, a filling material layer 24 is disposed on the second insulating layer 22 and the conductive member 23. In some embodiments, the filling material layer 24 may be or may include polyimide, epoxy, combinations thereof, or other suitable materials, but the present disclosure is not limited thereto.

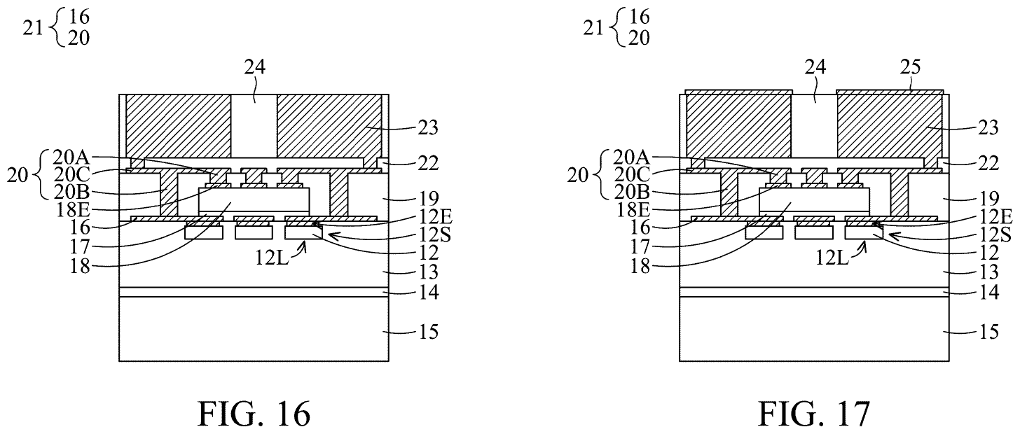

As shown in FIG. 16, a part of the filling material layer 24 is removed to expose the top surface of the conductive member 23. After a part of the filling material layer 24 is removed, the remaining filling material layer 24 surrounds the conductive member 23. In some embodiments, the filling material layer 24 may be removed through an etching process, a grinding process, other suitable processes, or combinations thereof, but the present disclosure is not limited thereto.

As shown in FIG. 17, a pad 25 is disposed on the top surface of the conductive member 23 exposed from the filling material layer 24. In some embodiments, the pad 25 may be or may include a conductive material. For example, the conductive material may include metal, metal compounds, other suitable conductive materials, or combinations thereof, but the present disclosure is not limited thereto. For example, the metal may be tin, copper, gold, silver, nickel, indium, platinum, palladium, iridium, titanium, chromium, tungsten, aluminum, molybdenum, titanium, magnesium, zinc, germanium, or alloys thereof. For example, the metal compound may be tantalum nitride, titanium nitride, tungsten silicide, indium tin oxide, etc. In some embodiments, the material of the pad 25 may be similar or the same as the material of the first redistribution layer 16, the second redistribution layer 20, or the conductive member 23, but the present disclosure is not limited thereto. In some embodiments, the material of the pad 25 is different from the material of the first redistribution layer 16, the second redistribution layer 20, or the conductive member 23.

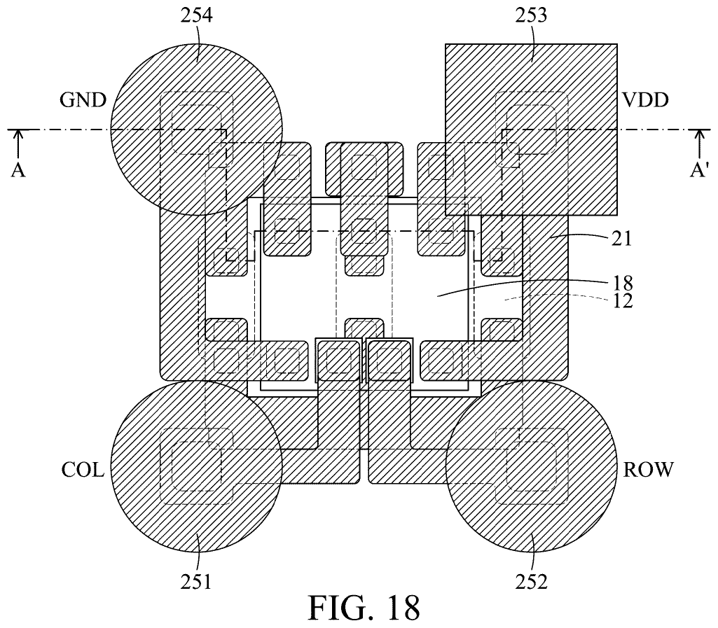

FIG. 18 is a schematic top view showing the micro light-emitting diode package structure. For ease of understanding, elements such as the light-transmitting layer 13, the second debond layer 14, the second substrate 15, the first insulating layer 19, the second insulating layer 22, and the filling material layer 24 are omitted in FIG. 18. As shown in the figure, the redistribution layer 21 electrically connects the column line COL (for example, select line), the row line ROW (for example, data line), the voltage source VDD, and the ground line GND through the conductive member 23 and the pad 25 disposed on the conductive member 23. Specifically, the pad 25 includes a pad 251 for connecting the column line COL (for example, select line) (using the reference numeral COL in the figure to indicate that the two are electrically connected), a pad 252 for connecting the row line ROW (for example, data line) (using the reference numeral ROW in the figure to indicate that the two are electrically connected), a pad 253 for connecting the voltage source VDD (using the reference numeral VDD in the figure to indicate that the two are electrically connected), and a pad 254 for connecting the ground line GND (using the reference numeral GND in the figure to indicate that the two are electrically connected). In this embodiment, the micro light-emitting diode package structure 1 has a common cathode LED structure.

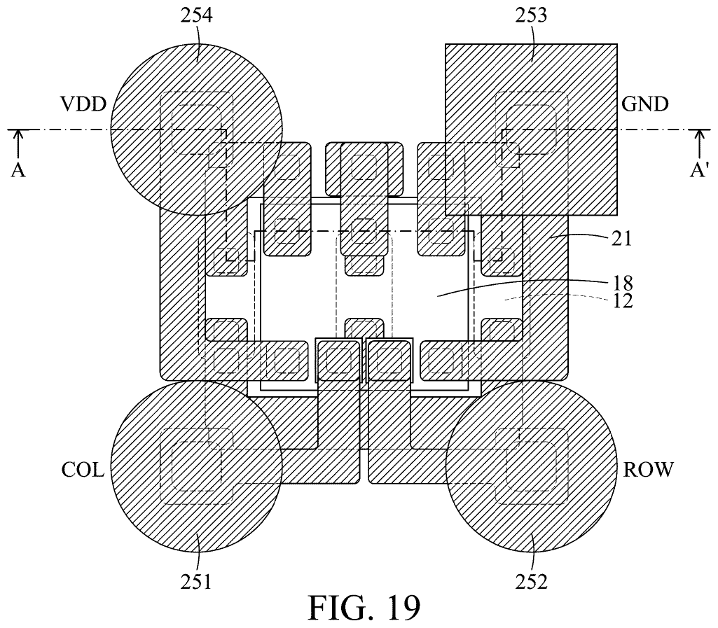

Alternatively, FIG. 19 is another schematic top view showing the micro light-emitting diode package structure. As shown in the figure, the pad 25 includes the pad 251 for connecting the column line COL (for example, select line) (using the reference numeral COL in the figure to indicate that the two are electrically connected), the pad 252 for connecting the row line ROW (for example, data line) (using the reference numeral ROW in the figure to indicate that the two are electrically connected), the pad 253 for connecting the ground line GND (using the reference numeral GND in the figure to indicate that the two are electrically connected), and the pad 254 for connecting the voltage source VDD (using the reference numeral VDD in the figure to indicate that the two are electrically connected). In this embodiment, the micro light-emitting diode package structure 1 has a common anode LED structure.

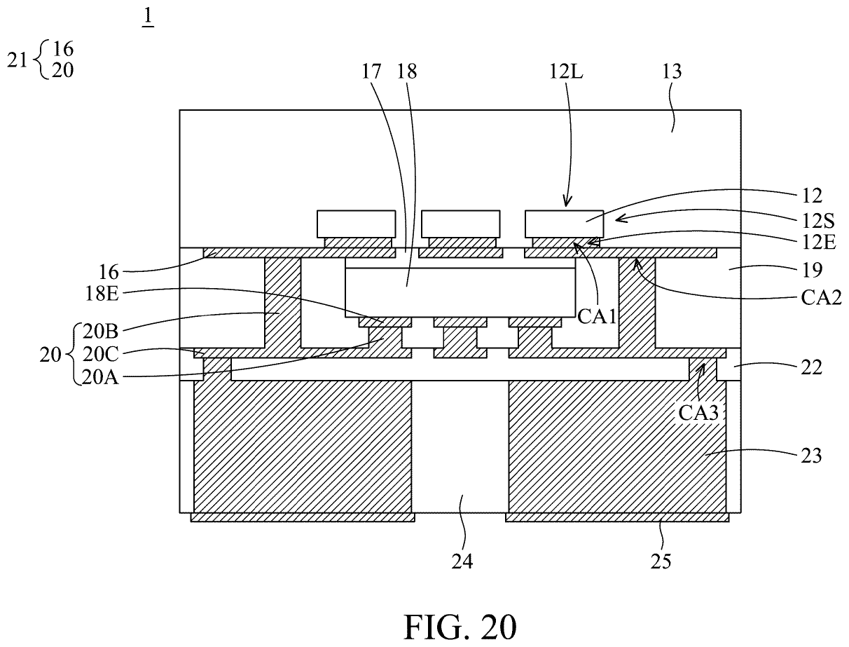

As shown in FIG. 20, following the above process, the second substrate 15 is turned over, and the second debond layer 14 and the second substrate 15 are removed. Specifically, FIG. 20 is the structure observed along the section line A-A′ of FIG. 18 or FIG. 19. In some embodiments, depending on the type of the second debond layer 14, the second debond layer 14 may lose its adhesion by heating, UV light, laser, etc., so as to remove the second substrate 15 thereon. Then, the second debond layer 14 may be removed by physical means or chemical means. It should be noted that the second debond layer 14 and the second substrate 15 may also be removed simultaneously in the same step using a suitable process, which is not limited to the above method. After the second debond layer 14 and the second substrate 15 are removed, the side of the light-transmitting layer 13 away from the micro light-emitting diode chip 12 is exposed, thereby forming the micro light-emitting diode package structure 1. In some embodiments, in the thickness direction of the micro light-emitting diode package structure 1, the light-transmitting layer 13, the first insulating layer 19, the second insulating layer 22, and the filling material layer 24 are coplanar.

In the present disclosure, in order to enable the driving element 18 to be disposed in the package structure without affecting the operation of the package structure, the specific redistribution structure is adopted. Specifically, the electrodes 18E of the driving element 18 face in the direction away from the electrode portion 12E of the micro light-emitting diode chip 12, and electrically connect the micro light-emitting diode chips 12 through the first redistribution layer 16 and the second redistribution layer 20 of the redistribution layer 21. In this case, the redistribution structure may have the following features, but the present disclosure is not limited thereto. For example, the first redistribution layer 16 and the electrode portion 12E have a first contact area CA1, the first redistribution layer 16 and the second redistribution layer 20 have a second contact area CA2, and the conductive member 23 and the second redistribution layer 20 have a third contact area CA3. The first contact area CA1, the second contact area CA2, and the third contact area CA3 do not overlap each other in the thickness direction of the micro light-emitting diode package structure 1 (that is, in the normal direction). By having connections between these features at specific locations, space may be used efficiently and the risk of short circuits between these features may be reduced.

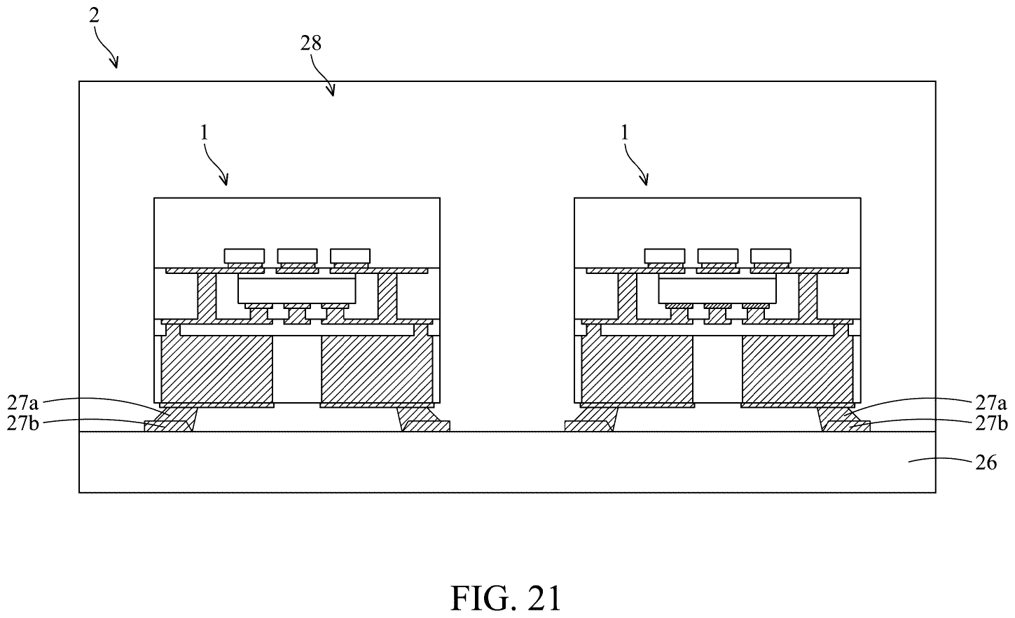

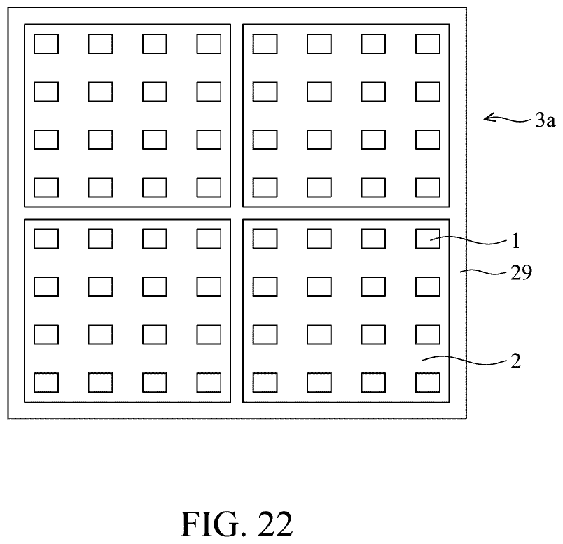

In some embodiments, the micro light-emitting diode chip 12 may be used as a pixel unit in a display device. For example, FIG. 21 and FIG. 22 are a schematic cross-sectional view and a schematic top view showing the display device according to some embodiments of the present disclosure. As shown in FIG. 21, multiple micro light-emitting diode package structures 1 may be disposed on the circuit board 26, and the micro light-emitting diode package structures 1 and the circuit board 26 are electrically connected through the bonding material 27a. Then, these micro light-emitting diode package structures 1 are encapsulated with the encapsulating material 28 to form the pixel module 2. In some embodiments, the bonding material 27a electrically connects the micro light-emitting diode package structures 1 and the conductive pad 27b of the circuit board 26. In some embodiments, the bonding material 27a and the conductive pad 27b may be or may include the conductive materials mentioned above, but the present disclosure is not limited thereto. In some embodiments, the material of the encapsulating material 28 may be similar to or the same as the material of the light-transmitting layer 13, but the present disclosure is not limited thereto. In some embodiments, the material of the encapsulation material 28 is different from the material of the light-transmitting layer 13, but the present disclosure is not limited thereto. In some embodiments, the light transmittance of the encapsulating material 28 is greater than the light transmittance of the filling material layer 24, but the present disclosure is not limited thereto. In some embodiments, the light transmittance of the encapsulation material 28 is greater than 85%. In some embodiments, the light transmittance of the encapsulating material 28 may be 86%, 87%, 88%, 89%, 90%, 91%, 92%, 93%, 94%, 95%, or any value or any range between the above values, but the present disclosure is not limited thereto. In some embodiments, the encapsulation material 28 is a transparent material, but the present disclosure is not limited thereto.

As shown in FIG. 22, the plurality of pixel modules 2 are disposed on the display substrate 29 to form the display device 3a. It should be noted that the number of pixel modules 2 and the number of micro light-emitting diode package structures 1 in the figure is only for illustration, and the present disclosure is not limited thereto. In other embodiments, the number of micro light-emitting diode package structures 1 in each pixel module 2 may be determined according to actual needs, and the number of pixel modules 2 in each display device 3a may also be determined according to actual needs.

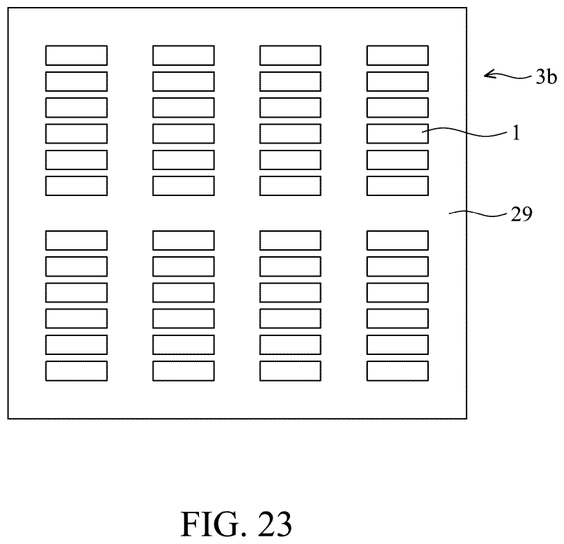

FIG. 23 is a schematic top view showing the display device according to other embodiments of the present disclosure. As shown in the figure, in addition to being disposed in the form of a pixel module, the micro light-emitting diode package structure 1 of the present disclosure may also be directly disposed on the display substrate 29 to form the display device 3b. In other words, the display device 3b in these embodiments may not include the circuit board 26 mentioned above.

As mentioned above, the micro light-emitting diode package structure 1 of the present disclosure may be used as a pixel unit and be directly or indirectly disposed on the display substrate in a periodic manner (for example, the embodiments in FIG. 22 or FIG. 23). In this case, in addition to allowing adjacent micro light-emitting diode chips 12 in a single micro light-emitting diode package structure 1 to share one anode or one cathode, it is also possible to allow adjacent driving elements 18 of the multiple micro light-emitting diode package structures 1 to share one anode or one cathode to further reduce the process complexity and the total number of circuits. Some embodiments of the present disclosure are provided hereinafter to illustrate how to make the driving elements 18 share one cathode.

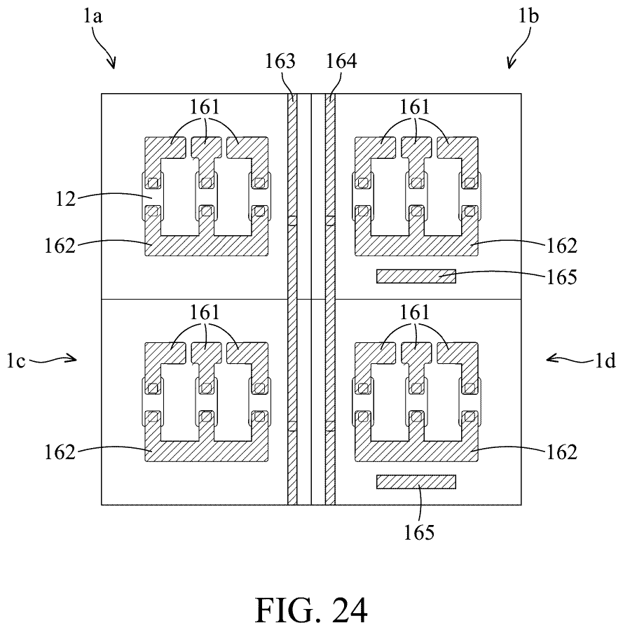

FIG. 24 is a schematic top view showing the micro light-emitting diode package structure according to other embodiments of the present disclosure. For ease of understanding, this figure roughly illustrates the relationship between the first redistribution layer 16 and the micro light-emitting diode chip 12. In some embodiments, the forming steps shown in FIG. 7 may be replaced with the forming steps shown in FIG. 24.

As shown in the figure, four micro light-emitting diode package structures 1a-1d may be regarded as one group. Among them, the formed first redistribution layer 16 includes the first sub-redistribution layer 161, the second sub-redistribution layer 162, a first main channel redistribution layer 163, a second main channel redistribution layer 164, and an eighth sub-redistribution layer 165. Specifically, the first main channel redistribution layer 163 extends through the micro light-emitting diode package structures 1a and 1c and is configured to electrically connect the voltage source VDD. On the other hand, the second main channel redistribution layer 164 extends through the micro light-emitting diode package structures 1b and 1d and is configured to electrically connect the ground line GND. The eighth sub-redistribution layer 165 is disposed in the micro light-emitting diode package structures 1c and 1d.

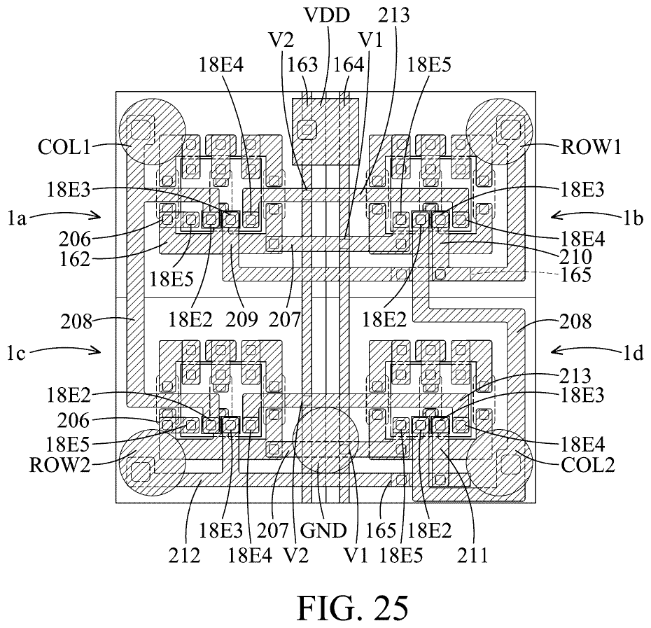

FIG. 25 is a schematic top view showing the micro light-emitting diode package structure according to other embodiments of the present disclosure. For ease of understanding, this figure roughly illustrates the relationship between the second redistribution layer 20, the driving element 18, and the first redistribution layer 16. In some embodiments, the forming steps shown in FIG. 18 may be replaced by the forming steps shown in FIG. 25.

As shown in the figure, the electrode 18E5 of the driving element 18 of the micro light-emitting diode package structure 1a may electrically connect the second sub-redistribution layer 162 of the first redistribution layer 16 through a ninth sub-redistribution layer 206 of the second redistribution layer 20. Then, the second sub-redistribution layer 162 of the first redistribution layer 16 electrically connects a tenth sub-redistribution layer 207 of the second redistribution layer 20. On the other hand, the tenth sub-redistribution layer 207 of the second redistribution layer 20 may electrically connect the electrodes 18E5 of the driving element 18 of the micro light-emitting diode package structure 1b and the second sub-redistribution layer 162 of the first redistribution layer 16. Finally, the tenth sub-redistribution layer 207 may electrically connect the second main channel redistribution layer 164 through a first via V1, thereby electrically connecting to the ground line GND.

Similarly, the electrode 18E5 of the driving element 18 of the micro light-emitting diode package structure 1c may electrically connect the second sub-redistribution layer 162 of the first redistribution layer 16 through the ninth sub-redistribution layer 206 of the second redistribution layer 20. Then, the second sub-redistribution layer 162 of the first redistribution layer 16 electrically connects the tenth sub-redistribution layer 207 of the second redistribution layer 20. On the other hand, the tenth sub-redistribution layer 207 of the second redistribution layer 20 may electrically connect the electrodes 18E5 of the driving element 18 of the micro light-emitting diode package structure 1d and the second sub-redistribution layer 162 of the first redistribution layer 16. Finally, the tenth sub-redistribution layer 207 may electrically connect the second main channel redistribution layer 164 through the first via V1, thereby electrically connecting to the ground line GND.

In other words, in this case, the driving elements 18 and the micro light-emitting diode chips 12 of the four micro light-emitting diode package structures 1a to 1d connect to the same ground line GND.

In some embodiments, the electrode 18E2 of the driving element 18 of the micro light-emitting diode package structure 1a and the electrode 18E2 of the driving element 18 of the micro light-emitting diode package structure 1c may also commonly and electrically connect the first column line COL1 (for example, select line) through the eleventh sub-redistribution layer 208. Similarly, the electrode 18E2 of the driving element 18 of the micro light-emitting diode package structure 1b and the electrode 18E2 of the driving element 18 of the micro light-emitting diode package structure 1d may also commonly and electrically connect the second column line COL2 (for example, select line) through the eleventh sub-redistribution layer 208. In other words, in this case, the driving elements 18 of the micro light-emitting diode package structures 1a and 1c commonly connect the same column line, and the driving elements 18 of the micro light-emitting diode package structures 1b and 1d commonly connect the same column line.

In some embodiments, the electrode 18E3 of the driving element 18 of the micro light-emitting diode package structure 1a may electrically connect the eighth sub-redistribution layer 165 of the first redistribution layer 16 through a twelfth sub-redistribution layer 209 of the second redistribution layer 20. Then, the eighth sub-redistribution layer 165 of the first redistribution layer 16 electrically connects a thirteenth sub-redistribution layer 210 of the second redistribution layer 20. On the other hand, the electrode 18E3 of the driving element 18 of the micro light-emitting diode package structure 1b directly and electrically connects the thirteenth sub-redistribution layer 210 of the second redistribution layer 20. Finally, the thirteenth sub-redistribution layer 210 electrically connects the first row line ROW1 (for example, data line). In other words, in this case, the driving elements 18 of the micro light-emitting diode package structures 1a and 1b commonly connect the same row line.

Similarly, the electrode 18E3 of the driving element 18 of the micro light-emitting diode package structure 1d may electrically connect the eighth sub-redistribution layer 165 of the first redistribution layer 16 through the fourteenth sub-redistribution layer 211 of the second redistribution layer 20. Then, the eighth sub-redistribution layer 165 of the first redistribution layer 16 electrically connects the fifteenth sub-redistribution layer 212 of the second redistribution layer 20. On the other hand, the electrode 18E3 of the driving element 18 of the micro light-emitting diode package structure 1c directly and electrically connects the fifteenth sub-redistribution layer 212 of the second redistribution layer 20. Finally, the fifteenth sub-redistribution layer 212 electrically connects the second row line ROW2 (for example, data line). In other words, in this case, the driving elements 18 of the micro light-emitting diode package structures 1c and 1d commonly connect the same row line.

In some embodiments, the electrodes 18E4 of the driving elements 18 of the micro light-emitting diode package structures 1a and 1b electrically connect a sixteenth sub-redistribution layer 213 of the second redistribution layer 20. Then, the sixteenth sub-redistribution layer 213 may electrically connect the first main channel redistribution layer 163 through the second via V2 to electrically connect the voltage source VDD. Similarly, the electrodes 18E4 of the driving elements 18 of the micro light-emitting diode package structures 1c and 1d electrically connect the sixteenth sub-redistribution layer 213 of the second redistribution layer 20. Then, the sixteenth sub-redistribution layer 213 may electrically connect the first main channel redistribution layer 163 through the second via V2 to electrically connect the voltage source VDD.

In other words, in this case, the driving elements 18 of the four micro light-emitting diode package structures 1a to 1d connect the same voltage source VDD. In this way, the process complexity and the total number of lines may be effectively reduced.

The components of the embodiments are outlined above so that those having ordinary knowledge in the art to which the present disclosure belongs may better understand the perspective of the embodiments of the present disclosure. Those having ordinary knowledge in the art to which the present disclosure belongs should understand that they may design or modify other processes or structures based on the embodiments of the present disclosure to achieve the same purposes and/or advantages as the embodiments described herein. Those having ordinary knowledge in the art to which the present disclosure belongs should also understand that such equivalent structures are not inconsistent with the spirit and scope of the present disclosure, and that they may make various changes, substitutions, and replacements without violating the spirit and scope of the present disclosure. Therefore, the scope of protection of the present disclosure is defined by the scope of the claim attached hereto. In addition, although several preferred embodiments are disclosed in the present disclosure, they are not intended to limit the present disclosure.

What is claimed is:

1. A micro light-emitting diode package structure, including:
a plurality of micro light-emitting diode chips disposed side by side, wherein the plurality of micro light-emitting diode chips each comprise an electrode portion and a light-emitting surface opposite to each other;
a light-transmitting layer covering the light-emitting surface of the plurality of micro light-emitting diode chips;
a first insulating layer disposed below the plurality of micro light-emitting diode chips;
a driving element disposed in the first insulating layer, wherein the driving element comprises a plurality of electrodes on a side of the driving element away from the plurality of micro light-emitting chips; and
a redistribution layer electrically connecting the electrode portion of the plurality of micro light-emitting diode chips and the plurality of electrodes of the driving element.

2. The micro light-emitting diode package structure as claimed in claim 1, wherein the redistribution layer comprises a first redistribution layer and a second redistribution layer disposed in the first insulating layer, wherein the first redistribution layer electrically connects the electrode portion of the plurality of micro light-emitting diode chips, and the second redistribution layer electrically connects the first redistribution layer and the plurality of electrodes of the driving element.

3. The micro light-emitting diode package structure as claimed in claim 2, wherein the first redistribution layer extends along a horizontal direction of the light-transmitting layer, wherein the second redistribution layer comprises a horizontal extension portion, and the second redistribution layer comprises a first vertical extension portion and a second vertical extension portion extending from the horizontal extension portion, wherein the horizontal extension portion extends along a bottom surface of the first insulating layer, the first vertical extension portion passes through the first insulating layer and electrically connects the driving element, and the second vertical extension portion passes through the first insulating layer and electrically connects the first redistribution layer.

4. The micro light-emitting diode package structure as claimed in claim 3, wherein a length of the second vertical extension is greater than a length of the first vertical extension.

5. The micro light-emitting diode package structure as claimed in claim 2, wherein the first redistribution layer and the electrode portion have a first contact area, and the first redistribution layer and the second redistribution layer have a second contact area, wherein the first contact area and the second contact area do not overlap each other in a thickness direction of the micro light-emitting diode package structure.

6. The micro light-emitting diode package structure as claimed in claim 2, further comprising a second insulating layer and a plurality of conductive members, wherein the second insulating layer is disposed below the first insulating layer, and the plurality of conductive members pass through the first insulating layer and electrically connect the second redistribution layer.

7. The micro light-emitting diode package structure as claimed in claim 6, wherein the plurality of conductive members and the second redistribution layer have a third contact area, the first redistribution layer and the electrode portion have a first contact area, and the first redistribution layer and the second redistribution layer have a second contact area, wherein the first contact area, the second contact area, and the third contact area do not overlap each other in a thickness direction of the micro light-emitting diode package structure.

8. The micro light-emitting diode package structure as claimed in claim 6, wherein the plurality of conductive members are metal pillars, and the micro light-emitting diode package structure further comprises a filling material layer, wherein the filling material layer is disposed below the second insulating layer and surrounds the plurality of conductive members.

9. The micro light-emitting diode package structure as claimed in claim 8, wherein the light-transmitting layer, the first insulating layer, the second insulating layer, and the filling material layer are coplanar.

10. The micro light-emitting diode package structure as claimed in claim 1, wherein the electrode portions of the plurality of micro light-emitting diode chips connect different anodes through the redistribution layer and connect the same cathode through the redistribution layer.

11. The micro light-emitting diode package structure as claimed in claim 10, wherein the plurality of micro light-emitting diode chips and the driving element commonly and electrically connect the same cathode through the redistribution layer.

12. The micro light-emitting diode package structure as claimed in claim 10, wherein the plurality of micro light-emitting diode chips and the driving element electrically connect different anodes through the redistribution layer.

13. The micro light-emitting diode package structure as claimed in claim 1, wherein the electrode portions of the plurality of micro light-emitting diode chips connect different cathodes through the redistribution layer and connect the same anode through the redistribution layer.

14. The micro light-emitting diode package structure as claimed in claim 13, wherein the plurality of micro light-emitting diode chips and the driving element commonly and electrically connect the same anode through the redistribution layer.

15. The micro light-emitting diode package structure as claimed in claim 13, wherein the plurality of micro light-emitting diode chips and the driving element electrically connect different cathodes through the redistribution layer.

16. The micro light-emitting diode package structure as claimed in claim 1, wherein the plurality of micro light-emitting diode chips further comprise a plurality of side surfaces between the light-emitting surface and the electrode portion, and the light-transmitting layer further covers the plurality of side surfaces.

17. The micro light-emitting diode package structure as claimed in claim 1, further comprising an adhesive layer disposed between the driving element and the plurality of micro light-emitting diode chips.

18. The micro light-emitting diode package structure as claimed in claim 1, wherein the driving element further electrically connects a column line, a row line, a voltage source, and a ground line through the redistribution layer.

19. The micro light-emitting diode package structure as claimed in claim 1, wherein the driving element comprises two transistors and one capacitor.

20. The micro light-emitting diode package structure as claimed in claim 1, wherein the plurality of micro light-emitting diode chips comprise a red LED chip, a blue LED chip, and a green LED chip, wherein the blue LED chip and the green LED chip have periodically arranged concave and convex textures, and the red LED chip has a non-uniform texture.
